(19) United States
(12) Patent Application Publication
(10) Pub. No.: US 2022/0399512 A1
(43) Pub. Date: Dec. 15, 2022

(54) DISPLAY PANEL AND DISPLAY DEVICE INCLUDING THE SAME

(71) Applicant: Samsung Display Co., Ltd., Yongin-Si (KR)

(72) Inventors: OK-KYUNG PARK, Hwaseong-si (KR); DONG-HYUN KIM, Pyeongtaek-si (KR); SUNGHOON KIM, Seoul (KR); YOUNG-SEOK SEO, Seoul (KR); YUNMI CHOI, Yongin-si (KR)

(21) Appl. No.: 17/728,267

(22) Filed: Apr. 25, 2022

(30) Foreign Application Priority Data
Jun. 15, 2021 (KR) 10-2021-0077275

(51) Int. Cl. H01L 51/00; H01L 27/32; H01L 51/52

(52) U.S. Cl. CPC H01L 51/0097; H01L 27/3246; H01L 27/3262; H01L 51/5253; H01L 2251/5338; H01L 27/124

(57) ABSTRACT

A display panel according to an embodiment may include a substrate and light emitting diodes disposed on the substrate. The substrate may include a first display area and a second display area which is disposed adjacent to the first display area and stretchable. The light emitting diodes disposed in the first display area and the second display area on the substrate. The second display area may include first through-parts extending in a first direction, and second through-parts extending in a second direction that is perpendicular to the first direction.

### CROSS-REFERENCE TO RELATED APPLICATION

This application claims priority to and the benefit of Korean Patent Application No. 10-2021-0077275, filed on Jun. 15, 2021, which is hereby incorporated by reference for all purposes as if fully set forth herein.

### BACKGROUND

### 1. Field

Embodiments of the present inventive concept relate to a display panel and a display device including the same. More particularly, Embodiments of the present inventive concept relate to a foldable display panel and a foldable display device including the same.

### 2. Description of the Related Art

Flat panel display devices are used as display devices for replacing a cathode ray tube display device due to lightweight and thin characteristics thereof. As representative examples of such flat panel display devices are a liquid crystal display device and an organic light emitting diode display device.

Recently, a flexible display device in which a substrate of a display panel included in the display device includes a flexible material and a display surface is deformable has been developed. For example, a foldable display device in which a portion of a display panel may be repeatedly folded and unfolded, a stretchable display device in which at least a portion of a display panel has stretchable and/or contractible characteristics, or the like has been developed.

### SUMMARY

Embodiments of the present inventive concept provide a display panel in which a display area is expandable.

Embodiments of the present inventive concept also provide a display device in which a display area is expandable.

Additional features of the inventive concepts will be set forth in the description which follows, and in part will be apparent from the description, or may be learned by practice of the inventive concepts.

A display panel according to an embodiment may include a substrate that may include a first display area and a second display area which is disposed adjacent to the first display area, and light emitting diodes disposed in the first display area and the second display area on the substrate. The second display area may include first through-parts extending in a first direction and second through-parts extending in a second direction that is perpendicular to the first direction.

In an embodiment, the first through-parts and the second through-parts may be alternately arranged in the first direction and the second direction.

In an embodiment, the second display area may be disposed adjacent to the first display area in the second direction, and may be stretchable in the second direction.

In an embodiment, a first width of each of the first through-parts in the second direction may be greater than a second width of each of the second through-parts in the first direction.

In an embodiment, the substrate may include a folding area folded about a folding axis and extending in the first direction. The folding area may overlap the first display area and spaced apart from the second display area.

In an embodiment, the second display area may be adjacent to the first display area in the first direction, and may be stretchable in the first direction.

In an embodiment, a first width of each of the first through-parts in the second direction may be smaller than a second width of each of the second through-parts in the first direction.

In an embodiment, the substrate may include a folding area folded about a folding axis and extending in the first direction. The folding area may overlap each of the first display area and the second display area.

In an embodiment, the display panel may further include pixel circuits disposed on the substrate and connected to the light emitting diodes, respectively. The second display area may include an overlapping area overlapping the folding area, and a non-overlapping area spaced apart from the folding area. A first pixel circuit may be connected to a first light emitting diode disposed in the non-overlapping area and disposed in the non-overlapping area. A second pixel circuit may be connected to a second light emitting diode disposed in the overlapping area and disposed in the first display area that is adjacent to the overlapping area.

In an embodiment, the first display area may include a first-first display area, a first-second display area disposed between the first-first display area and the second display area, and a first-third display area disposed between the first-second display area and the second display area. A first resolution of the first-first display area may be greater than each of a second resolution of the first-second display area and a third resolution of the first-third display area.

In an embodiment, a third pixel circuit connected to a third light emitting diode disposed in the first-first display area may be disposed in the first-first display area. A fourth pixel circuit connected to a fourth light emitting diode disposed in the first-second display area and a fifth pixel circuit connected to a fifth light emitting diode disposed in the first-third display area may be disposed in the first-second display area.

In an embodiment, the second pixel circuit may be disposed in the first-second display area.

In an embodiment, the display panel may further include a circuit structure disposed in the first-third display area on the substrate.

In an embodiment, a third pixel circuit connected to a third light emitting diode disposed in the first-first display area may be disposed in the first-first display area. A fourth pixel circuit connected to a fourth light emitting diode disposed in the first-second display area and a fifth pixel circuit connected to a fifth light emitting diode disposed in the first-third display area may be disposed in the first-third display area.

In an embodiment, the second pixel circuit may be disposed in the first-third display area.

In an embodiment, the display panel may further include a circuit structure disposed in the first-second display area on the substrate.

In an embodiment, the second display area may include a second-first display area, a second-second display area, and a second-third display area. The second-first display area may be disposed adjacent to the first display area in the second direction, and may be stretchable in the second direction. The second-second display area may be disposed adjacent to the first display area in the first direction, and may be stretchable in the first direction. The second-third display area may be disposed between the second-first display area and the second-second display area, and may be stretchable in a third direction between the first direction and the second direction.

In an embodiment, a first width of each of the first through-parts formed in the second-third display area in the second direction may be equal to a second width of each of the second through-parts formed in the second-third display area in the first direction.

In an embodiment, the first through-parts and the second through-parts may be formed through the substrate.

A display device according to an embodiment may include a display panel, a supporter disposed under the display panel, and a housing accommodating the display panel and the supporter. The display panel may include a first display area and a second display area. The second display area may be disposed adjacent to the first display area in a first direction and may be stretchable in the first direction. The supporter may include a hinge overlapping a folding axis, a first support part spaced apart from the second display area, and a second support part overlapping the second display area. The housing may include a first housing overlapping the first support part, and a second housing overlapping the second support part. The second display area may include first through-parts extending in the first direction and second through-parts extending in a second direction that is perpendicular to the first direction.

In an embodiment, the second support part or the second housing may be configured to guide stretching and contraction of the second display area of the display panel in the first direction.

In an embodiment, the first through-parts and the second through-parts may be formed through the substrate.

According to embodiments of the present disclosure, a display area of a display panel included in a display device may include a folding area folded and unfolded about a folding axis, and a non-folding area. In addition, the display area may include a first display area, and a second display area having stretchable and/or contractible characteristics. Accordingly, the display device can function as a foldable display device and a stretchable display device. As the second display area is stretched, the display device can display an image in a wider area by using an expanded display area, and provide various functions to a user.

In addition, the second display area of the display panel may include a first through-part extending in a first direction, and a second through-part extending in a second direction that is perpendicular to the first direction. The first through-part and the second through-part may have the same width or mutually different widths depending on a stretching direction of the second display area. Therefore, the stretchable and/or contractible characteristics of the second display area of the display panel can be improved.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIGS. 1a, 1b and 1c are sectional views showing a display device according to one embodiment of the present disclosure.

FIGS. 2a and 2b are plan views showing a display panel included in the display device of FIG. 1a.

FIG. 3 is an enlarged plan view showing a region “A” of FIG. 2a.

FIG. 4 is an enlarged plan view showing a region “B” of FIG. 2a.

FIG. 5 is a sectional view taken along line I-I′ of FIG. 3.

FIG. 6 is a sectional view taken along line II-II′ of FIG. 4.

FIG. 7 is a view showing examples of an expansion area of the display panel of FIG. 2b.

FIGS. 8a and 8b are plan views showing a display panel according to one embodiment of the present disclosure.

FIG. 9 is an enlarged plan view showing a region “C” of FIG. 8a.

FIGS. 10a and 10b are plan views showing a display panel according to one embodiment of the present disclosure.

FIG. 11 is an enlarged plan view showing a region “D” of FIG. 10a.

FIGS. 12a and 12b are sectional views showing a display panel according to one embodiment of the present disclosure.

FIGS. 13a and 13b are sectional views showing a display panel according to one embodiment of the present disclosure.

FIGS. 14a and 14b are sectional views showing a display panel according to one embodiment of the present disclosure.

### DETAILED DESCRIPTION OF THE EMBODIMENTS

Illustrative, non-limiting embodiments will be more clearly understood from the following detailed description in conjunction with the accompanying drawings.

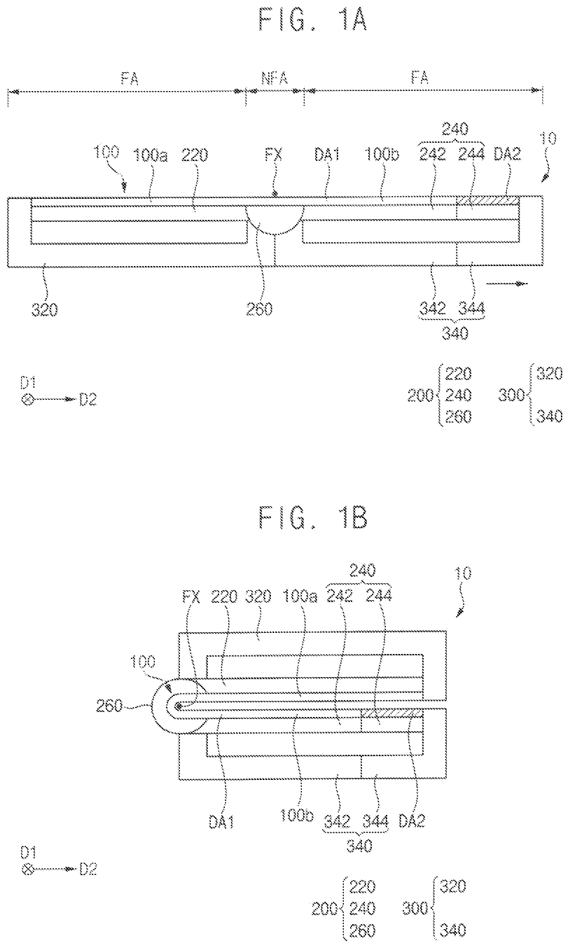

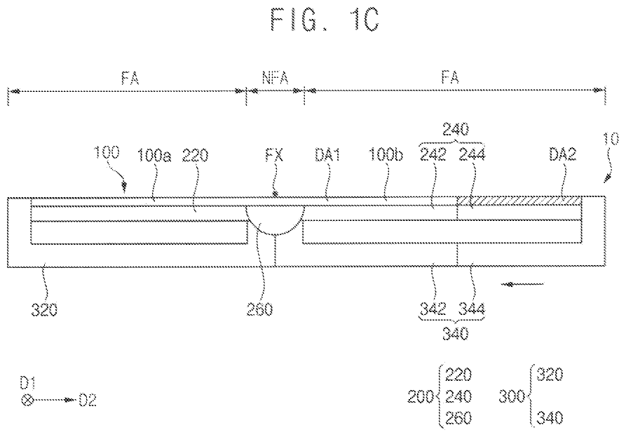

FIGS. 1a to 1c are sectional views showing a display device according to one embodiment of the present disclosure. For example, FIG. 1a may show a state in which a display device 10 is unfolded. FIG. 1B may show a state in which the display device 10 is folded. FIG. 1c may show a state in which the display device 10 is stretched in one direction when the display device is unfolded.

Referring to FIGS. 1a to 1c, according to one embodiment of the present disclosure, a display device 10 may include a display panel 100, a supporter 200, and a housing 300.

According to one embodiment, the display panel 100 may include a display area in which an image is displayed and a non-display area in which an image is not displayed. The display panel 100 may include a plurality of light emitting diodes disposed in the display area. Each of the light emitting diodes may include an organic light emitting diode, an inorganic light emitting diode, a quantum dot light emitting diode, or the like. The non-display area may be located at a periphery of the display area.

The display panel 100 may be folded and unfolded about a virtual folding axis FX extending in a first direction D1. In other words, the display panel 100 may be a foldable display panel.

As shown in FIG. 1a, when the display panel 100 is unfolded, the display panel 100 may include a first portion 100a located on one side of the folding axis FX, and a second portion 100b located on an opposite side of the first portion 100a with respect to the folding axis FX. As shown in FIG. 1B, when the display panel 100 is folded about the folding axis FX, the first part 100a may face the second part 100b.

According to one embodiment, the display device 10 may further include a sub-display panel (not shown) facing the first part 100a of the display panel 100. When the display device 10 is folded, the display device 10 may display an image through the sub-display panel. The sub-display panel may be formed separately from the display panel 100, or may be formed integrally with the display panel 100.

At least a portion of the display panel 100 may have stretchable and/or contractible characteristics. In other words, the display panel 100 may be a stretchable display panel.

According to one embodiment, the display area may include a first display area DA1 and a second display area DA2. The light emitting diodes may be disposed in the first display area DA1 and the second display area DA2. The second display area DA2 may have better stretchability than the first display area DA1. The second display area DA2 may be disposed adjacent to the first display area DA1 in a second direction D2 that is perpendicular to the first direction D1. The second display area DA2 may be stretchable and/or contractible in the second direction D2 and a direction that is opposite to the second direction D2.

According to one embodiment, the second display area DA2 may be located at one end of the second part 100b that is away from the first part 100a. As shown in FIG. 1a, when the second display area DA2 is not stretched in the second direction D2, a length of the second part 100b in the second direction D2 may be substantially equal to a length of the first part 100a in the second direction D2. As shown in FIG. 1c, when the second display area DA2 is stretched in the second direction D2, the length of the second part 100b in the second direction D2 may be greater than the length of the first part 100a in the second direction D2.

The supporter 200 may be disposed under the display panel 100. The supporter 200 may include a first support part 220, a second support part 240, and a hinge 260. According to one embodiment, various functional layers such as a protective layer, a cushion layer, and a heat dissipation layer may be disposed between the display panel 100 and the supporter 200.

The first support part 220 may be coupled to a lower portion of the first part 100a of the display panel 100 to support the first part 100a. The second support part 240 may be coupled to a lower portion of the second part 100b of the display panel 100 to support the second part 100b.

The hinge 260 may be coupled to a lower portion of the display panel 100 to overlap the folding axis FX. The hinge 260 may connect the first support part 220 to the second support part 240. Each of the first support part 220 and the second support part 240 may be rotated about the folding axis FX through the hinge 260.

The housing 300 may accommodate the display panel 100 and the supporter 200. The first display area DA1 and the second display area DA2 of the display panel 100 may be exposed to outside from the housing 300. The housing 300 may include a first housing 320 and a second housing 340.

The first housing 320 may accommodate the first part 100a of the display panel 100 and the first support part 220. The second housing 340 may accommodate the second part 100b of the display panel 100 and the second support part 240. Each of the first housing 320 and the second housing 340 may be rotated about the folding axis FX through the hinge 260.

The second support part 240 may include a first part 242 and a second part 244. The first part 242 may be disposed corresponding to a lower portion of the first display area DA1 of the second part 100b of the display panel 100. The second part 244 may be disposed corresponding to a lower portion of the second display area DA2 of the second part 100b of the display panel 100.

The second housing 340 may include a first part 342 and a second part 344. The first part 342 may be disposed corresponding to a lower portion of the first display area DA1 of the second part 100b of the display panel 100. The second part 344 may be disposed corresponding to a lower portion of the second display area DA2 of the second part 100b of the display panel 100.

According to one embodiment, the second part 244 of the second support part 240 and the second part 344 of the second housing 340 may guide the second display area DA2 of the display panel 100 in the second direction D2 and the direction that is opposite to the second direction D2 when the display panel is stretched or contracted. For example, each of the second part 244 of the second support part 240 and the second part 344 of the second housing 340 may be stretchable in the second direction D2. For example, the second part 244 of the second support part 240 and the second part 344 of the second housing 340 may be slidably coupled to the first part 242 of the second support part 240 and the first part 342 of the second housing 340 in the second direction D2, respectively.

According to one embodiment, one end of the second part 244 of the second support part 240 or one end of the second part 344 of the second housing 340 may be coupled to one end of the first part 242 of the second support part 240 and the first part 342 of the second housing 340, respectively, in the second direction D2. When the one end of the second part 244 of the second support part 240 or the one end of the second part 344 of the second housing 340 moves away from the folding axis FX in the second direction D2, as shown in FIG. 1c, the second display area DA2 of the display panel 100 may be stretched in the second direction D2. On the contrary, when the one end of the second part 244 of the second support part 240 or the one end of the second part 344 of the second housing 340 moves toward the folding axis FX in the direction that is opposite to the second direction D2, as shown in FIG. 1a, the second display area DA2 of the display panel 100 may be contracted in the direction that is opposite to the second direction D2. Meanwhile, although FIG. 1c only shows that the second display area DA2 of the display panel 100 is stretched in the second direction D2 when the display device 10 is unfolded (FIG. 1a), according to one embodiment, the second display area DA2 of the display panel 100 may be stretched in the second direction D2 even when the display device 10 is folded (FIG. 1B).

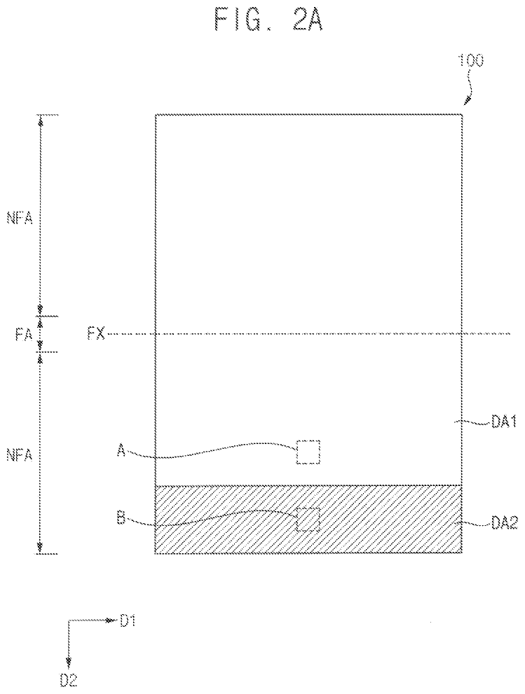

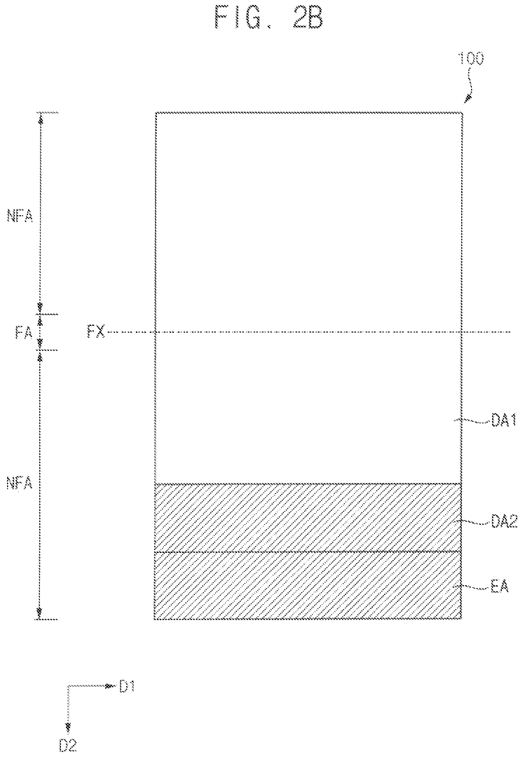

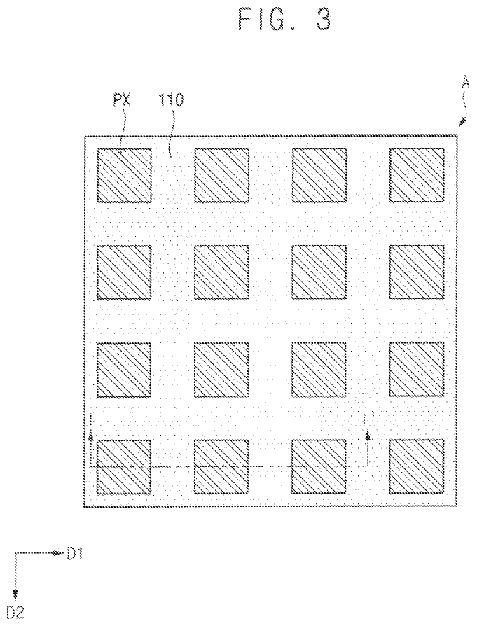

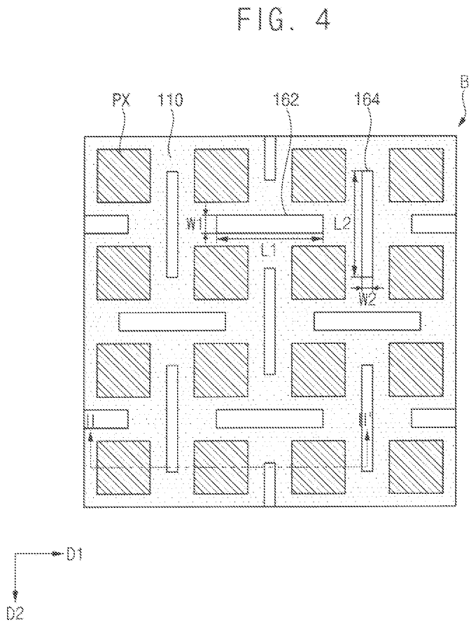

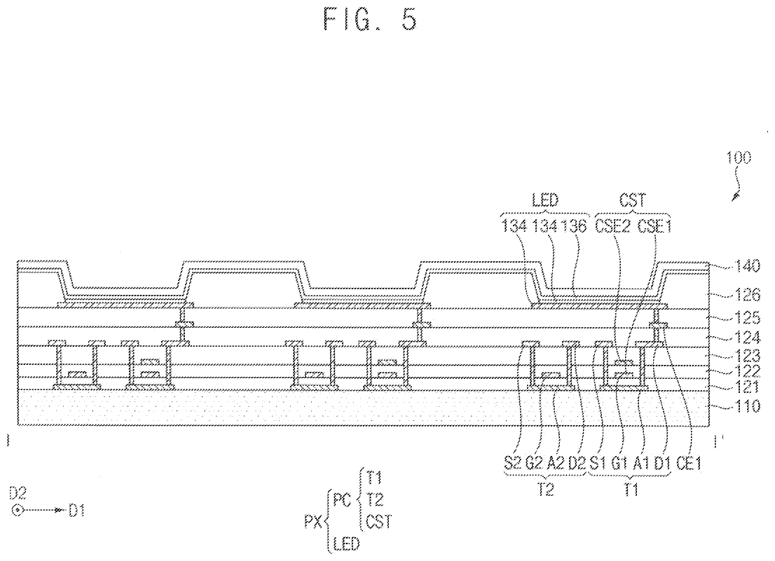

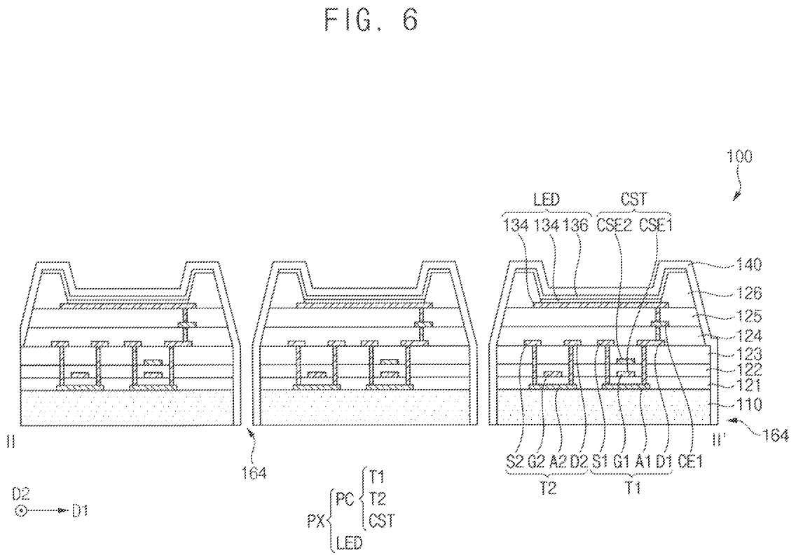

FIGS. 2a and 2b are plan views showing a display panel included in the display device of FIG. 1a. FIG. 3 is an enlarged plan view showing a region “A” of FIG. 2a. FIG. 4 is an enlarged plan view showing a region “B” of FIG. 2a. FIG. 5 is a sectional view taken along line I-I′ of FIG. 3. FIG. 6 is a sectional view taken along line II-II′ of FIG. 4. For example, FIGS. 2a and 2b may show the display area of the display panel 100. FIG. 2b may show a state in which the display panel 100 of FIG. 2a is stretched in the second direction D2.

Referring to FIGS. 2a to 6, according to one embodiment, the display panel 100 may include a substrate 110, and a plurality of pixels PX disposed on the substrate 110. Each of the pixels PX may include a pixel circuit PC and a light emitting diode LED. The pixel circuit PC may provide a driving current to the light emitting diode LED. The light emitting diode LED may emit a light based on the driving current. The pixel circuit PC may include at least one transistor and at least one capacitor to generate the driving current. For example, the pixel circuit PC may include a first transistor T1, a second transistor T2, and a storage capacitor CST. However, the present disclosure is not limited to the above configuration, and the pixel circuit PC may include at least three transistors and/or at least two capacitors.

According to one embodiment, each of the pixels PX may include a plurality of sub-pixels configured to emit lights having mutually different colors. For example, each of the pixels PX may include a first sub-pixel configured to emit light having a first color, a second sub-pixel configured to emit light having a second color, and a third sub-pixel configured to emit light having a third color. The first color may be red, the second color may be green, and the third color may be blue. In other words, each of the pixels PX may include a unit pixel which includes the first to third sub-pixels. In this case, the first sub-pixel may include a first light emitting diode and a first sub-pixel circuit, the second sub-pixel may include a second light emitting diode and a second sub-pixel circuit, and the third sub-pixel may include a third light emitting diode and a third sub-pixel circuit. In other words, the pixel circuit PC may include the first to third sub-pixel circuits, and the light emitting diode LED may include the first to third light emitting diodes. The first to third sub-pixels may be arranged in various forms (e.g., in a stripe scheme, a PENTILE™ scheme, etc.) within each of the pixels PX.

According to another embodiment, each of the pixels PX may emit light having one of the first to third colors. In other words, each of the pixels PX may include one of the first to third sub-pixels.

The substrate 110 may be a flexible insulating substrate. For example, the substrate 110 may include a polymer resin. Examples of the polymer resin may include polyethersulphone, polyacrylate, polyetherimide, polyethylene naphthalate, polyethylene terephthalate, polyphenylene sulfide, polyarylate, polyimide, polycarbonate, cellulose acetate propionate, and/or the like. These may be used alone or in combination with each other. According to one embodiment, the substrate 110 may have a structure in which at least one polymer resin layer and at least one barrier layer are alternately stacked.

The substrate 110 (or the display panel 100) may include the display area and the non-display area. According to one embodiment, the display area may include a folding area FA folded about the folding axis FX, and a non-folding area NFA. The folding area FA may extend in the first direction D1 and may be located at a central portion of the display area. The non-folding area NFA may be located in the second direction D2 and the direction that is opposite to the second direction D2 with the folding area FA interposed therebetween.

In addition, the display area may include a first display area DA1 and a second display area DA2. The second display area DA2 may have better stretchability than the first display area DA1.

According to one embodiment, the second display area DA2 may be located on one side of the first display area DA1. The second display area DA2 may be disposed adjacent to the first display area DA1 in the second direction D2. The second display area DA2 may be disposed in the non-folding area NFA and may not be disposed in the folding area FA. The second display area DA2 may extend in the first direction D1 and may be spaced apart from the folding area FA in the second direction D2.

As shown in FIGS. 2a and 2b, the second display area DA2 may be stretchable and/or contractible in the second direction D2. In other words, the second display area DA2 may be stretched and contracted in the second direction D2 and in the direction that is opposite to the second direction D2. When the second display area DA2 is stretched in the second direction D2, the display area of the display panel 100 may be expanded by a predetermined expansion area EA. The expansion area EA may extend in the first direction D1.

As shown in FIGS. 3 and 4, the pixels PX may be disposed in the first display area DA1 and the second display area DA2 on the substrate 110. For example, the pixels PX may be spaced apart from each other and arranged in a matrix form in the first direction D1 and the second direction D2.

The second display area DA2 of the substrate 110 may include first through-parts 162 and second through-parts 164. Each of the first through-parts 162 may extend in the first direction D1 between adjacent pixels. Each of the second through-parts 164 may extend in the second direction D2 between adjacent pixels.

According to one embodiment, when the substrate 110 has the structure in which the at least one polymer resin layer and the at least one barrier layer are alternately stacked, the first through-parts 162 and the second through-parts 164 may be formed through both the polymer resin layer and the barrier layer.

According to one embodiment, as shown in FIG. 4, the first through-parts 162 and the second through-parts 164 may be alternately arranged in the first direction D1 and the second direction D2. Each of the first through-parts 162 and each of the second through-parts 164 may be spaced apart from the pixels PX. In detail, two pixels PX may be disposed on each of upper and lower sides of the first through-part 162 so as to vertically correspond to each other with the first through-part 162 interposed therebetween. In addition, two pixels PX may be disposed on each of left and right sides of the second through-part 164 so as to horizontally correspond to each other with the second through-part 164 interposed therebetween. However, the above configuration has been provided for illustrative purposes, so the present disclosure is not limited thereto.

According to one embodiment, each of the first through-parts 162 and each of the second through-parts 164 formed in the second display area DA2 may have mutually different widths (e.g., widths in a direction that is perpendicular to a longitudinal direction).

According to one embodiment, a first width W1 of each of the first through-parts 162 in the second direction D2 may be greater than a second width W2 of each of the second through-parts 164 in the first direction D1. Accordingly, stretchable and/or contractible characteristics of the second display area DA2 of the substrate 110 in the second direction D2 may be improved.

According to one embodiment, a first length L1 of each of the first through-parts 162 in the first direction D1 may be substantially equal to a second length L2 of each of the second through-parts 164 in the second direction D2. According to another embodiment, the first length L1 may be smaller than or greater than the second length L2.

The through-parts may not be formed in the first display area DA1 of the substrate 110. Accordingly, the first display area DA1 of the substrate 110 may rarely have stretchable and/or contractible characteristics.

The pixel circuit PC may be disposed on the substrate 110. The pixel circuit PC may include a first transistor T1, a second transistor T2, and a storage capacitor CST.

The first transistor T1 may include an active layer A1, a gate electrode G1, a source electrode S1, and a drain electrode D1. The first transistor T1 may be a driving transistor connected to the light emitting diode LED. The second transistor T2 may include an active layer A2, a gate electrode G2, a source electrode S2, and a drain electrode D2. The second transistor T2 may be a switching transistor connected to a data wire. The storage capacitor CST may include a first electrode CSE1 and a second electrode CSE2.

The active layers A1 and A2 may be disposed on the substrate 110. Each of the active layers A1 and A2 may include an oxide semiconductor, a silicon semiconductor, an organic semiconductor, or the like. For example, the oxide semiconductor may include oxide of at least one of indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include amorphous silicon, polycrystalline silicon, or the like. Each of the active layers A1 and A2 may include a source region, a drain region, and a channel region located between the source region and the drain region.

According to one embodiment, although not shown in the drawings, a buffer layer may be disposed between the substrate 110 and the active layers A1 and A2. The buffer layer may prevent impurities from diffusing from the substrate 110 to the active layers A1 and A2. The buffer layer may include an inorganic insulating material such as a silicon compound or metal oxide. Examples of the inorganic insulating material may include silicon oxide (SiOₓ), silicon nitride (SiNₓ), silicon oxynitride (SiOₓN_{y}), silicon oxycarbide (SiOₓC_{y}), silicon carbonitride (SiCₓN_{y}), aluminum oxide (AlOₓ), aluminum nitride (AlNₓ), tantalum oxide (TaOₓ), hafnium oxide (HfOₓ), zirconium oxide (ZrOₓ), titanium oxide (TiOₓ), and/or the like. These may be used alone or in combination with each other. The buffer layer may have a single-layer structure, or a multilayer structure including a plurality of insulating layers.

A first insulating layer 121 may be disposed on the active layers A1 and A2. The first insulating layer 121 may cover the active layers A1 and A2 on the substrate 110. The first insulating layer 121 may include an inorganic insulating material.

The gate electrodes G1 and G2 may be disposed on the first insulating layer 121. The gate electrode G1 may overlap the channel region of the active layer A1 and the gate electrode G2 may overlap the channel region of the active layer A2. Each of the gate electrodes G1 and G2 may include a conductive material such as a metal, an alloy, conductive metal nitride, conductive metal oxide, or a transparent conductive material. Examples of the conductive material may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an aluminum-containing alloy, a silver-containing alloy, a copper-containing alloy, a molybdenum-containing alloy, aluminum nitride (AlNₓ), tungsten nitride (WNₓ), titanium nitride (TiNₓ), chromium nitride (CrNₓ), tantalum nitride (TaNₓ), strontium ruthenium oxide (SrRuₓO_{y}), zinc oxide (ZnOₓ), indium tin oxide (ITO), tin oxide (SnOₓ), indium oxide (InOₓ), gallium oxide (GaOₓ), indium zinc oxide (IZO), or the like. These may be used alone or in combination with each other. Each of the gate electrodes G1 and G2 may have a single-layer structure, or a multilayer structure including a plurality of conductive layers.

A second insulating layer 122 may be disposed on the gate electrodes G1 and G2. The second insulating layer 122 may cover the gate electrodes G1 and G2 on the first insulating layer 121. The second insulating layer 122 may include an inorganic insulating material.

The first electrode CSE1 of the storage capacitor CST may overlap the first transistor T1. For example, the gate electrode G1 of the first transistor T1 may function as the first electrode CSE1 of the storage capacitor CST.

The second electrode CSE2 of the storage capacitor CST may be disposed on the second insulating layer 122. The second electrode CSE2 may overlap the first electrode CSE1. The second electrode CSE2 may include a conductive material.

A third insulating layer 123 may be disposed on the second electrode CSE2 of the storage capacitor CST. The third insulating layer 123 may cover the second electrode CSE2 on the second insulating layer 122. The third insulating layer 123 may include an inorganic insulating material.

The source electrodes S1 and S2 and the drain electrodes D1 and D2 may be disposed on the third insulating layer 123. The source electrode S1 and the drain electrode D1 may be connected to the source region and the drain region of the active layer A1, respectively. The source electrode S2 and the drain electrode D2 may be connected to the source region and the drain region of the active layer A2, respectively. Each of the source electrodes S1 and S2 and the drain electrodes D1 and D2 may include a conductive material.

A fourth insulating layer 124 may be disposed on the source electrodes S1 and S2 and the drain electrodes D1 and D2. The fourth insulating layer 124 may include an organic insulating material. Examples of the organic insulating material may include a photoresist, a polyacryl-based resin, a polyimide-based resin, a polyamide-based resin, a siloxane-based resin, an acryl-based resin, an epoxy-based resin, or the like. These may be used alone or in combination with each other.

A connection electrode CE1 may be disposed on the fourth insulating layer 124. The connection electrode CE1 may be connected to the drain electrode D1 of the first transistor T1 through a contact hole formed in the fourth insulating layer 124. The connection electrode CE1 may include a conductive material.

A fifth insulating layer 125 may be disposed on the connection electrode CE1. The fifth insulating layer 125 may include an organic insulating material.

The light emitting diode LED may be disposed on the fifth insulating layer 125. The light emitting diode LED may include a pixel electrode 132, a light emitting layer 134, and a common electrode 136.

The pixel electrode 132 may be disposed on the fifth insulating layer 125. The pixel electrode 132 may be connected to the connection electrode CE1 through a contact hole formed in the fifth insulating layer 125. Accordingly, the pixel electrode 132 may be electrically connected to the drain electrode D1 of the first transistor T1. The pixel electrode 132 may include a conductive material.

A sixth insulating layer 126 may be disposed on the pixel electrode 132. The sixth insulating layer 126 may cover a peripheral portion of the pixel electrode 132 and include a pixel opening that exposes a central portion of the pixel electrode 132. The sixth insulating layer 126 may include an organic insulating material.

The light emitting layer 134 may be disposed on the pixel electrode 132. The light emitting layer 134 may be disposed in the pixel opening of the sixth insulating layer 126. According to one embodiment, the light emitting layer 134 may include at least one of an organic light emitting material and a quantum dot.

According to one embodiment, the organic light emitting material may include a low molecular weight organic compound or a high molecular weight organic compound.

Examples of the low molecular weight organic compound may include copper phthalocyanine, N,N′-diphenylbenzidine, tris-(8-hydroxyquinoline)aluminum, and the like. Examples of the high molecular weight organic compound may include poly(3,4-ethylenedioxythiophene), polyaniline, poly-phenylenevinylene, polyfluorene, and the like. These may be used alone or in combination with each other.

According to one embodiment, the quantum dot may include a core including a group II-VI compound, a group III-V compound, a group IV-VI compound, a group IV element, a group IV compound, or a combination thereof. According to one embodiment, the quantum dot may have a core-shell structure including the core and a shell surrounding the core. The shell may serve as a protective layer for maintaining semiconductor characteristics by preventing chemical modification of the core and serve as a charging layer for imparting electrophoretic characteristics to the quantum dot.

The common electrode 136 may be disposed on the light emitting layer 134. The common electrode 136 may also be disposed on the sixth insulating layer 126. The common electrode 136 may include a conductive material.

An encapsulation layer 140 may be disposed on the common electrode 136. The encapsulation layer 140 may include at least one inorganic encapsulation layer and at least one organic encapsulation layer. According to one embodiment, the encapsulation layer 140 may include a first inorganic encapsulation layer disposed on the common electrode 136, an organic encapsulation layer disposed on the first inorganic encapsulation layer, and a second inorganic encapsulation layer disposed on the organic encapsulation layer.

According to one embodiment, as shown in FIGS. 4 and 6, each of the first through-part 162 and the second through-part 164 formed in the second display area DA2 may be formed through the substrate 110, the first insulating layer 121, the second insulating layer 122, the third insulating layer 123, the fourth insulating layer 124, the fifth insulating layer 125, and the sixth insulating layer 126. In addition, each of the first through-part 162 and the second through-part 164 may be formed through the common electrode 136. The encapsulation layer 140 may cover side surfaces of the substrate 110, the first insulating layer 121, the second insulating layer 122, the third insulating layer 123, the fourth insulating layer 124, the fifth insulating layer 125, the sixth insulating layer 126, and the common electrode 136 through which the first through-part 162 and the second through-part 164 are formed. In other words, the encapsulation layer 140 may be deposited on the substrate 110 after the first through-part 162 and the second through-part 164 are formed.

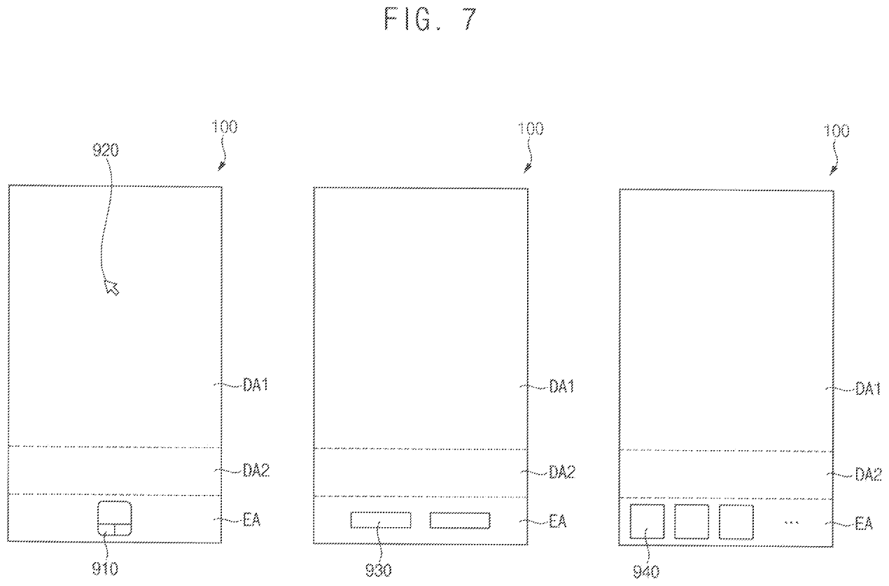

FIG. 7 is a view showing examples of an expansion area of the display panel of FIG. 2b.

Referring to FIGS. 2a, 2b, and 7, the display device 10 may display an image in a wider area by using the expansion area EA when the display device is stretched. In addition, according to one embodiment, the display panel 100 may further include a touch sensing layer disposed in the first display area DA1 and the second display area DA2. The touch sensing layer may sense a touch of a user in a capacitive scheme. Accordingly, the display device 10 may provide various functions to the user in a wider area by using the expansion area EA.

When the display panel 100 is not stretched, a virtual keypad (not shown) may be displayed in a partial region of the display area (e.g., a lower region of the display area). The touch sensing layer may sense the touch of the user on the partial region so that the display device 10 may receive a key input of the user.

As shown in a left drawing of FIG. 7, when the display panel 100 is stretched, a first icon 910 may be displayed in the expansion area EA of the display panel 100 and a cursor 920 may be displayed in the display area that is located on an upper side of the expansion area EA. The first icon 910 may have a touch pad shape. The touch sensing layer may sense the touch of the user on the expansion area EA so that the display device 10 may receive a click input, a drag input, and the like in addition to the key input of the user.

As another example, as shown in a middle drawing of FIG. 7, when the display panel 100 is stretched, at least one second icon 930 may be displayed in the expansion area EA of the display panel 100. The user may select and store one of various functions (e.g., screen enlargement/reduction, screen scrolling, etc.) for each of the second icons 930. Thereafter, the touch sensing layer may sense the touch of the user on the expansion area EA so that the display device 10 may receive a touch input of the user for the second icon 930. The display device 10 may perform a function corresponding to the second icon 930 through which the touch input is received.

As still another example, as shown in a right drawing of FIG. 7, when the display panel 100 is stretched, at least one third icon 940 may be displayed in the expansion area EA of the display panel 100. For example, each of the third icons 940 may represent a document that the user recently worked on. The touch sensing layer may sense the touch of the user on the expansion area EA so that the display device 10 may receive a touch input of the user for the third icon 940. The display device 10 may display a document corresponding to the third icon 940 through the touch input is received. However, the above configuration has been provided for illustrative purposes, so the present disclosure is not limited thereto.

According to embodiments of the present disclosure, the display area of the display panel 100 may include the folding area FA folded and unfolded about the folding axis FX, and the non-folding area NFA. In addition, the display area may include the first display area DA1, and the second display area DA2 which is stretchable and/or contractible, independently of the folding area FA and the non-folding area NFA. Accordingly, the display device 10 may function as a foldable and stretchable display device. When the second display area DA2 is stretched, the display device 10 may display an image in a wider area than the second display area DA2 is retracted by using the expansion area EA which is an expanded display area, and provide various functions to the user.

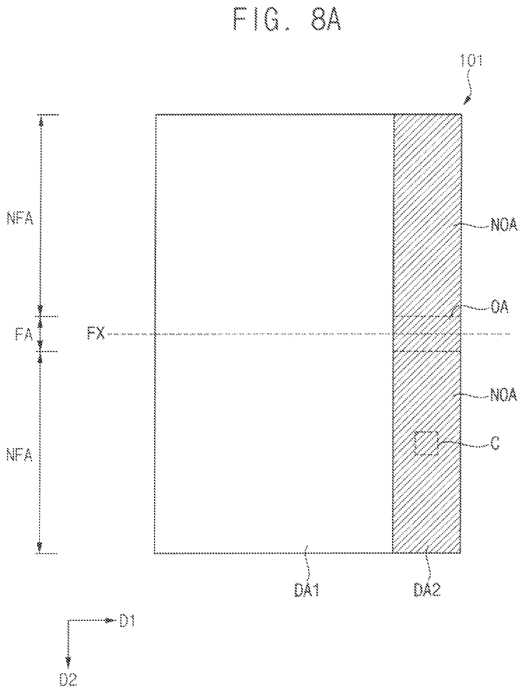

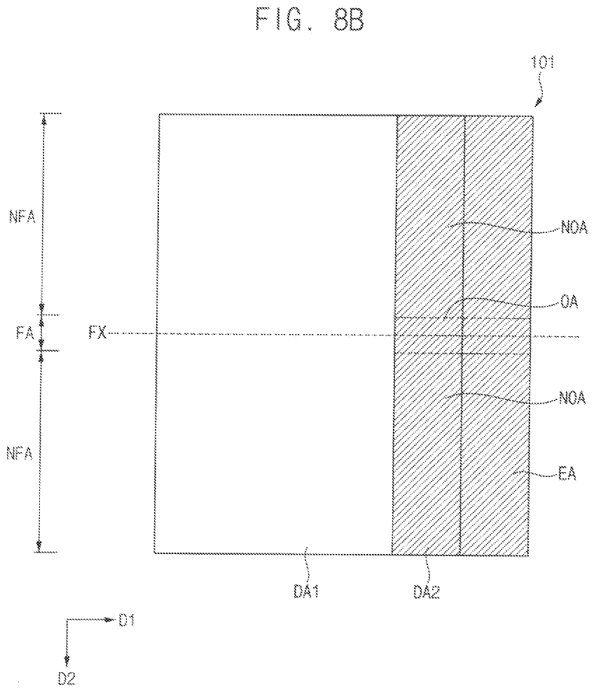

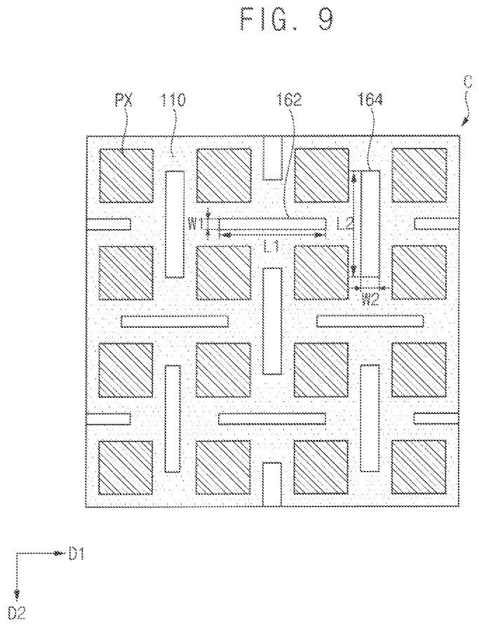

FIGS. 8a and 8b are plan views showing a display panel according to one embodiment of the present disclosure. FIG. 9 is an enlarged plan view showing a region “C” of FIG. 8a. A display panel 101 according to one embodiment, which will be described with reference to FIGS. 8a to 9, may be substantially identical or similar to the display panel 100 according to one embodiment which has been described with reference to FIGS. 2a to 6 except for the second display area DA2. Therefore, redundant descriptions thereof will be omitted or briefly given.

Referring to FIGS. 8a to 9, the substrate 110 (or the display panel 101) may include the display area and the non-display area. The display area may include a first display area DA1 and a second display area DA2. The second display area DA2 may be an area which is more stretchable and/or contractible than the first display area DA1.

According to one embodiment, the second display area DA2 may be located on one side of the first display area DA1. The second display area DA2 may be disposed adjacent to the first display area DA1 in the first direction D1. The second display area DA2 may extend in the second direction D2. The second display area DA2 may overlap each of the folding area FA and the non-folding area NFA. The second display area DA2 may include an overlapping area OA overlapping the folding area FA, and a non-overlapping area NOA that does not overlap the folding area FA. The non-overlapping area NOA may overlap the non-folding area NFA.

As shown in FIGS. 8a and 8b, the second display area DA2 may be stretchable and/or contractible in the first direction DE In other words, the second display area DA2 may be stretched and contracted in the first direction D1 and a direction that is opposite to the first direction DE When the second display area DA2 is stretched in the first direction D1, the display area of the display panel 101 may be expanded by a predetermined expansion area EA. For example, the expansion area EA may extend in the first direction D1.

The pixels PX may be disposed in the first display area DA1 and the second display area DA2 on the substrate 110. The second display area DA2 of the substrate 110 may include first through-parts 162 and second through-parts 164. Each of the first through-parts 162 may extend in the first direction D1. Each of the second through-parts 164 may extend in the second direction D2.

According to one embodiment, as shown in FIG. 9, each of the first through-parts 162 and each of the second through-parts 164 formed in the second display area DA2 may have mutually different widths (e.g., widths in a direction that is perpendicular to a longitudinal direction).

According to one embodiment, a first width W1 of each of the first through-parts 162 in the second direction D2 may be smaller than a second width W2 of each of the second through-parts 164 in the first direction DE Accordingly, stretchable and/or contractible characteristics of the second display area DA2 of the substrate 110 in the first direction D1 may be improved.

According to one embodiment, a first length L1 of each of the first through-parts 162 in the first direction D1 may be substantially equal to a second length L2 of each of the second through-parts 164 in the second direction D2. According to another embodiment, the first length L1 may be smaller than or greater than the second length L2.

The through-parts may not be formed in the first display area DA1 of the substrate 110. Accordingly, the first display area DA1 of the substrate 110 may rarely have stretchable and/or contractible characteristics.

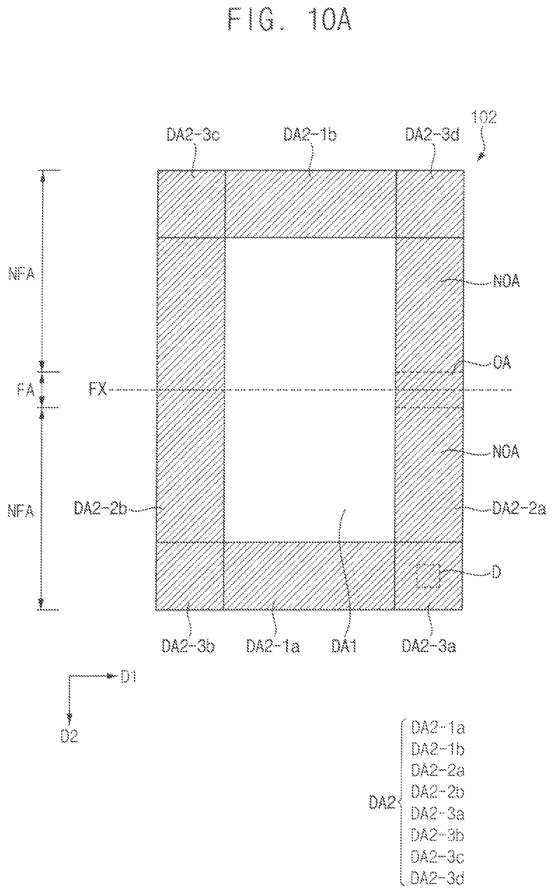

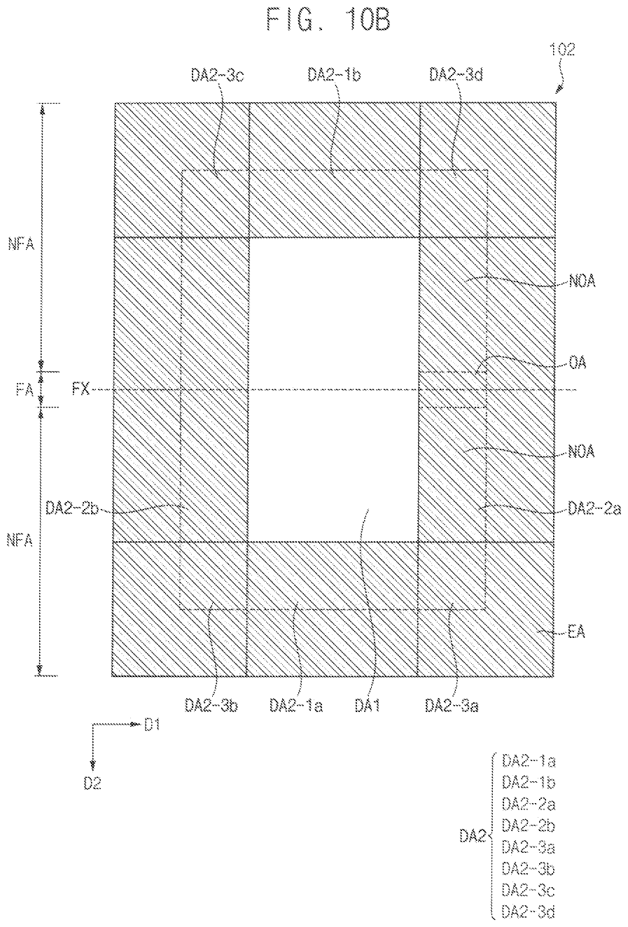

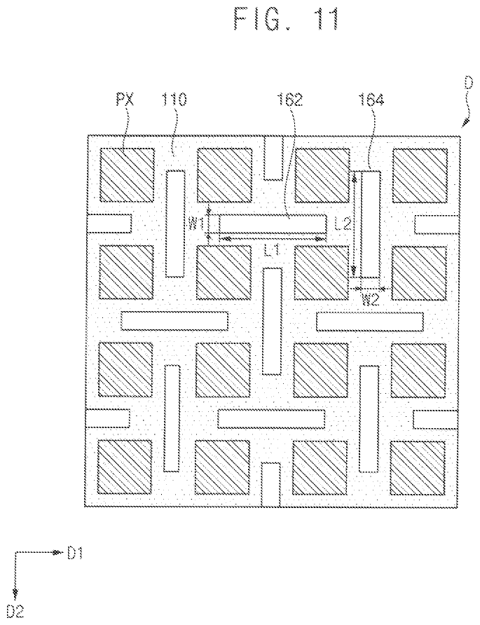

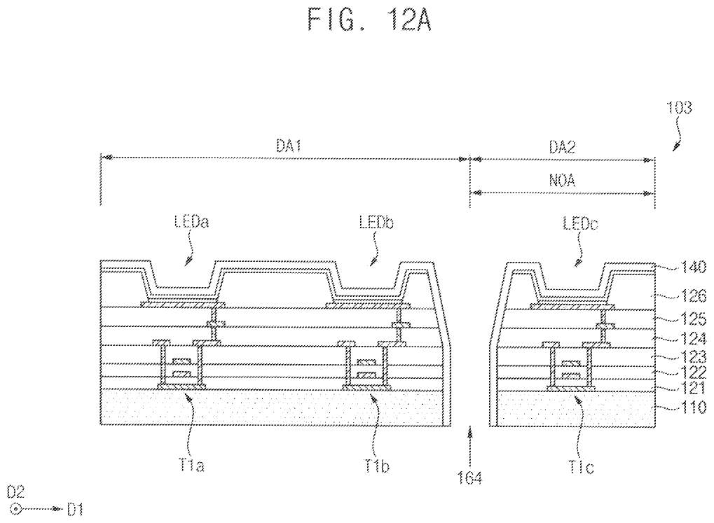

FIGS. 10a and 10b are plan views showing a display panel according to one embodiment of the present disclosure. FIG. 11 is an enlarged plan view showing a region “D” of FIG. 10a. A display panel 102 according to one embodiment, which will be described with reference to FIGS. 10a to 11, may be substantially identical or similar to the display panel 100 according to one embodiment, which has been described with reference to FIGS. 2a to 6, or the display panel 101 according to one embodiment, which has been described with reference to FIGS. 8a to 9, except for the second display area DA2. Therefore, redundant descriptions thereof will be omitted or briefly given.

Referring to FIGS. 10a to 11, the substrate 110 (or the display panel 102) may include the display area and the non-display area. The display area may include a first display area DA1 and a second display area DA2. The second display area DA2 may be stretchable and/or contractible in the first display area DA1.

According to one embodiment, the second display area DA2 may partially surround the first display area DA1 or completely surround the first display area DA1. For example, the second display area DA2 may include second-first display areas DA2-1a and DA2-1b, second-second display areas DA2-2a and DA2-2b, and second-third display areas DA2-3a, DA2-3b, DA2-3c, and DA2-3d. In other words, the second display area DA2 may be disposed adjacent to upper, lower, left, and right sides of the first display area DA1. According to another embodiment, the second display area DA2 may be disposed adjacent only to the lower and right sides of the first display area DA1.

The second-first display areas DA2-1a and DA2-1b may be disposed adjacent to the first display area DA1 in the second direction D2 and the direction that is opposite to the second direction D2, respectively. Each of the second-first display areas DA2-1a and DA2-1b may be stretchable and/or contractible in the second direction D2. In other words, each of the second-first display areas DA2-1a and DA2-1b may be stretchable and/or contractible in the second direction D2 and the direction that is opposite to the second direction D2. Each of the second-first display areas DA2-1a and DA2-1b may overlap the non-folding area NFA, and may not overlap the folding area FA.

The second-second display areas DA2-2a and DA2-2b may be disposed adjacent to the first display area DA1 in the first direction D1 and the direction that is opposite to the first direction D1, respectively. Each of the second-second display areas DA2-2a and DA2-2b may be stretchable and/or contractible in the first direction D1. In other words, each of the second-second display areas DA2-2a and DA2-2b may be stretchable and/or contractible in the first direction D1 and the direction that is opposite to the first direction D1. Each of the second-second display areas DA2-2a and DA2-2b may overlap each of the folding area FA and the non-folding area NFA. Each of the second-second display areas DA2-2a and DA2-2b may include an overlapping area OA overlapping the folding area FA, and a non-overlapping area NOA that does not overlap the folding area FA. The non-overlapping area NOA may overlap the non-folding area NFA.

The second-third display area DA2-3a may be located between the second-first display area DA2-1a and the second-second display area DA2-2a. The second-third display area DA2-3a may be stretchable and/or contractible in a third direction between the first direction D1 and the second direction D2. That is, the second-third display area DA2-3a may be stretched and contracted in the third direction and a direction that is opposite to the third direction. In other words, the second-third display area DA2-3a may be simultaneously stretched in the first direction D1 and the second direction D2, or simultaneously contracted in the direction that is opposite to the first direction D1 and the direction that is opposite to the second direction D2.

Each of the second-third display areas DA2-3b, DA2-3c, and DA2-3d may correspond to the second-third display area DA2-3a. Therefore, redundant descriptions thereof will be omitted.

When the second display area DA2 is simultaneously stretched in the first direction D1 and the second direction D2, the display area of the display panel 102 may be expanded by a predetermined expansion area EA. For example, the expansion area EA may have a shape surrounding the first display area DA1 while being spaced apart from the first display area DA1.

The pixels PX may be disposed in the first display area DA1 and the second display area DA2 on the substrate 110. The second display area DA2 of the substrate 110 may include first through-parts 162 and second through-parts 164. Each of the first through-parts 162 may extend in the first direction D1. Each of the second through-parts 164 may extend in the second direction D2.

According to one embodiment, each of the first through-parts 162 and each of the second through-parts 164 formed in the second-first display areas DA2-1a and DA2-1b of the substrate 110 may have mutually different widths (e.g., widths in a direction that is perpendicular to a longitudinal direction). For example, as shown in FIG. 4, a first width W1 of each of the first through-parts 162 formed in the second-first display areas DA2-1a and DA2-1b of the substrate 110 in the second direction D2 may be greater than a second width W2 of each of the second through-parts 164 in the first direction D1. Accordingly, stretchable and/or contractible characteristics of each of the second-first display areas DA2-1a and DA2-1b of the substrate 110 in the second direction D2 may be improved.

According to one embodiment, each of the first through-parts 162 and each of the second through-parts 164 formed in the second-second display areas DA2-2a and DA2-2b of the substrate 110 may have mutually different widths (e.g., widths in a direction that is perpendicular to a longitudinal direction). For example, as shown in FIG. 9, a first width W1 of each of the first through-parts 162 formed in the second-second display areas DA2-2a and DA2-2b of the substrate 110 in the second direction D2 may be smaller than a second width W2 of each of the second through-parts 164 in the first direction D1. Accordingly, stretchable and/or contractible characteristics of each of the second-second display areas DA2-2a and DA2-2b of the substrate 110 in the first direction D1 may be improved.

According to one embodiment, each of the first through-parts 162 and each of the second through-parts 164 formed in the second-third display areas DA2-3a, DA2-3b, DA2-3c, and DA2-3d of the substrate 110 may have the same width (e.g., a width in a direction perpendicular to a longitudinal direction). For example, as shown in FIG. 11, a first width W1 of each of the first through-parts 162 formed in the second-third display areas DA2-3a, DA2-3b, DA2-3c, and DA2-3d of the substrate 110 in the second direction D2 may be substantially equal to a second width W2 of each of the second through-parts 164 in the first direction D1. Accordingly, stretchable and/or contractible characteristics of each of the second-third display areas DA2-3a, DA2-3b, DA2-3c, and DA2-3d of the substrate 110 in the third direction may be improved.

The through-parts may not be formed in the first display area DA1 of the substrate 110. Accordingly, the first display area DA1 of the substrate 110 may rarely have stretchable and/or contractible characteristics.

According to embodiments of the present disclosure, the display area of the display panel 100 may include the folding area FA which is foldable and unfoldable about the folding axis FX, and the non-folding area NFA. In addition, the display area may include the first display area DA1 and the second display area DA2 having stretchable and/or contractible characteristics. Accordingly, the display device 10 may function as a foldable and/or stretchable display device. In addition, the second display area DA2 of the display panel 100 may include the first through-part 162 extending in the first direction D1 and the second through-part 164 extending in the second direction D2. The first through-part 162 and the second through-part 164 may have the same width or mutually different widths depending on a stretching direction of the second display area DA2. Therefore, the stretchable and/or contractible characteristics of the second display area DA2 of the display panel 100 may be improved.

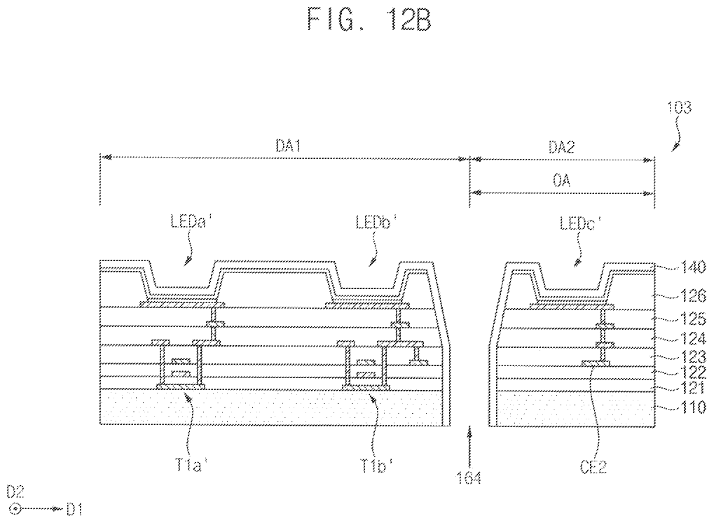

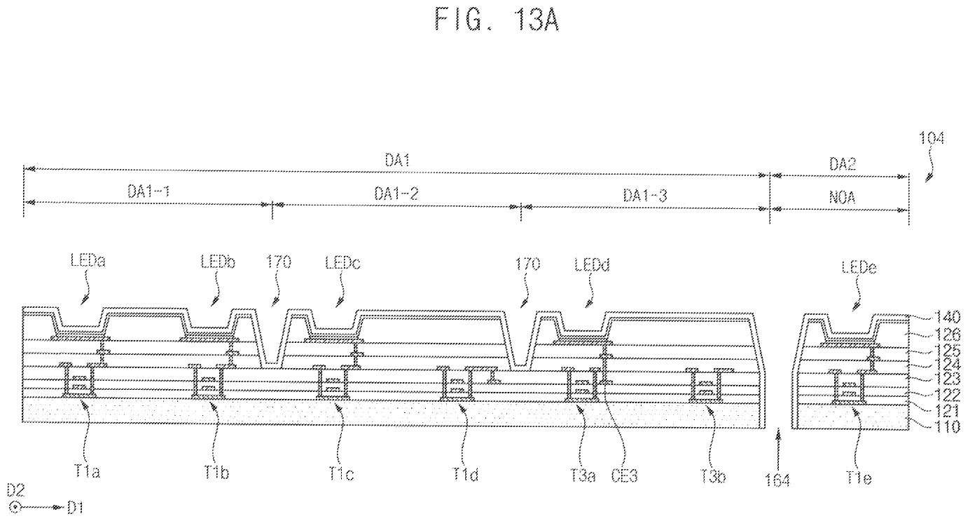

FIGS. 12a and 12b are sectional views showing a display panel according to one embodiment of the present disclosure. For example, a display panel 103 shown in FIGS. 12a and 12b may correspond to the display panel 101 of FIG. 8a or the display panel 102 of FIG. 10a in which the second display area DA2 having the stretchable and/or contractible characteristics overlaps the folding area FA.

For example, FIG. 12a may show a boundary between the non-overlapping area NOA of the second display area DA2 that does not overlap the folding area FA, and the first display area DA1 disposed adjacent to the non-overlapping area NOA. FIG. 12b may show a boundary between the overlapping area OA of the second display area DA2 that overlaps the folding area FA, and the first display area DA1 disposed adjacent to the overlapping area OA.

Meanwhile, although only first transistors T1a, T1a′, T1b, T1b′, and T1c and storage capacitors in pixel circuits PC have been shown in FIGS. 12a and 12b for brevity, a second transistor T2 may also be disposed in an area close to each of the first transistors T1a, T1a′, T1b, T1b′, and T1c. In addition, a description of each of the first transistors T1a, T1a′, T1b, T1b′, and T1c that will be described below may be similarly applied to pixel circuits PC including the first transistors T1a, T1a′, T1b, T1b′, and T1c.

Referring to FIG. 12a, light emitting diodes LEDa and LEDb may be disposed in the first display area DA1 that is adjacent to the non-overlapping area NOA of the second display area DA2. The first transistors T1a and T1b connected to the light emitting diodes LEDa and LEDb, respectively, may be disposed in the first display area DA1. For example, the first transistors T1a and T1b may overlap the light emitting diodes LEDa and LEDb, respectively.

A light emitting diode LEDc may be disposed in the non-overlapping area NOA of the second display area DA2 that is adjacent to the first display area DA1. The first transistor T1c connected to the light emitting diode LEDc may be disposed in the non-overlapping area NOA of the second display area DA2. For example, the first transistor T1c may overlap the light emitting diode LEDc. In other words, both the light emitting diode LEDc and the first transistor T1c may be disposed in the non-overlapping area NOA of the second display area DA2 that has stretchable and/or contractible characteristics in the first direction D1 and does not overlap the folding area FA.

Referring to FIG. 12b, light emitting diodes LEDa′ and LEDb′ may be disposed in the first display area DA1 that is disposed adjacent to the overlapping area OA of the second display area DA2. The first transistors T1a′ and T1b′ connected to the light emitting diodes LEDa′ and LEDb′, respectively, may be disposed in the first display area DAL For example, the first transistors T1a′ and T1b′ may overlap the light emitting diodes LEDa′ and LEDb′, respectively.

A light emitting diode LEDc′ may be disposed in the overlapping area OA of the second display area DA2 that is disposed adjacent to the first display area DAL A first transistor connected to the light emitting diode LEDc′ may not be disposed in the overlapping area OA of the second display area DA2. In other words, the light emitting diode LEDc′ may be disposed in the overlapping area OA of the second display area DA2 that has stretchable and/or contractible characteristics in the first direction D1 and overlaps the folding area FA, whereas the first transistor connected to the light emitting diode LEDc′ may not be disposed in the overlapping area OA of the second display area DA2 that has stretchable and/or contractible characteristics in the first direction D1 and overlaps the folding area FA.

According to one embodiment, the first transistor connected to the light emitting diode LEDc′ may be disposed in the first display area DA1 that is disposed adjacent to the overlapping area OA of the second display area DA2. The light emitting diode LEDc′ may be connected to the first transistor through the connection electrode CE2. For example, as shown in the drawing, the connection electrode CE2 may be disposed on the same layer as the second electrode CSE2 of the storage capacitor CST. As another example, the connection electrode CE2 may be disposed on the same layer as one of the active layer A1, the gate electrode G1, the source electrode S1, the drain electrode D1, and the connection electrode CE1.

According to one embodiment, the first transistor connected to the light emitting diode LEDc′ may be the first transistor T1b′ connected to the light emitting diode LEDb′. For example, one first transistor disposed in the first display area DA1 that is adjacent to the overlapping area OA of the second display area DA2 may be connected to n light emitting diodes (where n is an integer greater than or equal to 2).

According to one embodiment, the first transistor connected to the light emitting diode LEDc′ may be a first transistor that is not connected to another light emitting diode. For example, one first transistor disposed in the first display area DA1 that is adjacent to the overlapping area OA of the second display area DA2 may be connected to one light emitting diode.

According to embodiments of the present disclosure, the light emitting diodes LED may be disposed in the second display area DA2 having the stretchable and/or contractible characteristics. A portion of the second display area DA2 may overlap the folding area FA. Both the light emitting diode LED and the pixel circuit PC may be disposed in the non-overlapping area NOA of the second display area DA2 that does not overlap the folding area FA. The light emitting diode LED may be disposed in the overlapping area OA of the second display area DA2 that overlaps the folding area FA, whereas the pixel circuit PC may not be disposed in the overlapping area OA of the second display area DA2 that overlaps the folding area FA. The light emitting diode LED disposed in the overlapping area OA may be connected to the pixel circuit PC disposed in the adjacent first display area DA1. Accordingly, the pixel circuit PC may be prevented from being damaged in the overlapping area OA in which the folding area FA folded about the folding axis FX overlaps the second display area DA2 stretchable and/or contractible in one direction. Therefore, reliability of the display device 10 may be improved, and display quality may be improved.

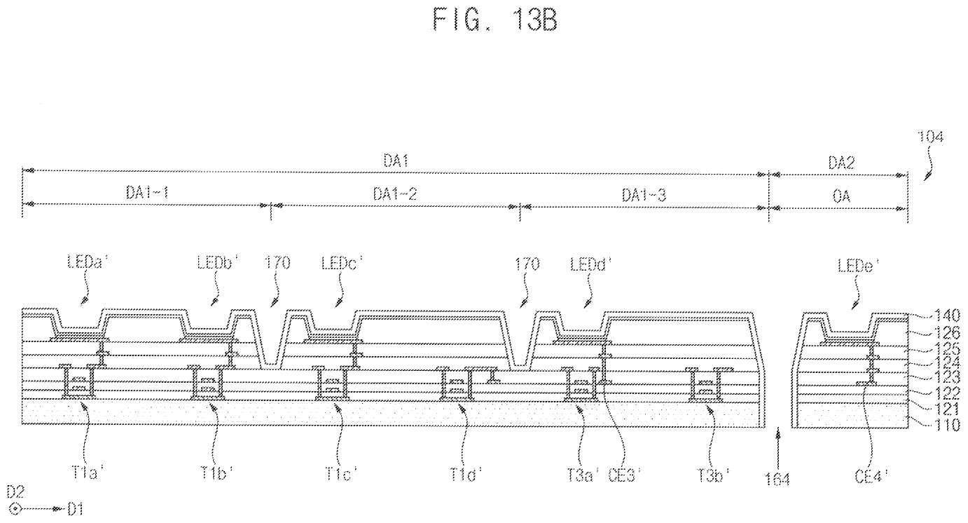

FIGS. 13a and 13b are sectional views showing a display panel according to one embodiment of the present disclosure. For example, a display panel 104 shown in FIGS. 13a and 13b may correspond to the display panel 101 of FIG. 8a or the display panel 102 of FIG. 10a in which the second display area DA2 having the stretchable and/or contractible characteristics overlaps the folding area FA.

For example, FIG. 13a may show a boundary between the non-overlapping area NOA of the second display area DA2 that does not overlap the folding area FA, and the first display area DA1 disposed adjacent to the non-overlapping area NOA. FIG. 13b may show a boundary between the overlapping area OA of the second display area DA2 that overlaps the folding area FA, and the first display area DA1 disposed adjacent to the overlapping area OA.

Meanwhile, although only first transistors T1a, T1a′, T1b, T1b′, T1c, T1c′, T1d, T1d′, and T1e and storage capacitors in pixel circuits PC have been shown in FIGS. 13a and 13b for brevity, a second transistor T2 may be disposed in a region close to each of the first transistors T1a, T1a′, T1b, T1b′, T1c, T1c′, T1d, T1d′, and T1e. In addition, a description of each of the first transistors T1a, T1a′, T1b, T1b′, T1c, T1c′, T1d, T1d′, and T1e that will be described below may be similarly applied to pixel circuits PC including the first transistors T1a, T1a′, T1b, T1b′, T1c, T1c′, T1d, T1d′, and T1e.

Referring to FIGS. 13a and 13b, the first display area DA1 may include a first-first display area DA1-1, a first-second display area DA1-2, and a first-third display area DA1-3. The first-third display area DA1-3 may be disposed adjacent to the second display area DA2. The first-second display area DA1-2 may be spaced apart from the second display area DA2 with the first-third display area DA1-3 interposed therebetween. The first-first display area DA1-1 may be spaced apart from the second display area DA2 with the first-second display area DA1-2 and the first-third display area DA1-3 interposed therebetween. In other words, the first-first display area DA1-1 may be located at a central portion of the first display area DA1, and the first-third display area DA1-3 may be located at an outermost periphery portion of the first display area DAL

According to one embodiment, the first through-part 162 and the second through-part 164 may be formed in the second display area DA2. The first through-part 162 and the second through-part 164 may not be formed in each of the first-first display area DA1-1, the first-second display area DA1-2, and the first-third display area DA1-3.

According to one embodiment, a third through-part 170 may be formed at boundaries between the first-first display area DA1-1 and the first-second display area DA1-2, and between the first-second display area DA1-2 and the first-third display area DA1-3. The third through-part 170 may be formed through the fourth insulating layer 124, the fifth insulating layer 125, and the sixth insulating layer 126. The third through-part 170 may not be formed through the substrate 110, the first insulating layer 121, the second insulating layer 122, and the third insulating layer 123.

Referring to FIG. 13a, light emitting diodes LEDa and LEDb may be disposed in the first-first display area DA1-1 that is disposed close to the non-overlapping area NOA of the second display area DA2. The first transistors T1a and T1b connected to the light emitting diodes LEDa and LEDb, respectively, may be disposed in the first-first display area DA1-1. The first transistors T1a and T1b may overlap the light emitting diodes LEDa and LEDb, respectively.

A light emitting diode LEDc may be disposed in the first-second display area DA1-2 that is disposed close to the non-overlapping area NOA of the second display area DA2. The first transistor T1c connected to the light emitting diode LEDc may be disposed in the first-second display area DA1-2. For example, the first transistor T1c may overlap the light emitting diode LEDc. According to one embodiment, a first transistor T1d may be further disposed in the first-second display area DA1-2.

A light emitting diode LEDd may be disposed in the first-third display area DA1-3 that is disposed adjacent to the non-overlapping area NOA of the second display area DA2. A first transistor connected to the light emitting diode LEDd may not be disposed in the first-third display area DA1-3. In other words, the light emitting diode LEDd may be disposed in the first-third display area DA1-3, whereas the first transistor connected to the light emitting diode LEDd may not be disposed in the first-third display area DA1-3.

According to one embodiment, the first transistor connected to the light emitting diode LEDd may be disposed in the first-second display area DA1-2 which is disposed adjacent to the first-third display area DA1-3. The light emitting diode LEDd may be connected to the first transistor in the first-second display area DA1-2 through a connection electrode CE3.

According to one embodiment, the first transistor connected to the light emitting diode LEDd may be the first transistor T1d that is not connected to another light emitting diode. For example, one first transistor disposed in the first-second display area DA1-2 that is disposed close to the non-overlapping area NOA of the second display area DA2 may be connected to one light emitting diode disposed in the first-third display area DA1-3).

According to one embodiment, the first transistor connected to the light emitting diode LEDd may the first transistor T1c connected to the light emitting diode LEDc. One first transistor disposed in the first-second display area DA1-2 that is disposed close to the non-overlapping area NOA of the second display area DA2 may be connected to m light emitting diodes (where m is an integer greater than or equal to 2), for example, a light emitting diode disposed in the first-second display area DA1-2 and a light emitting diode disposed in the first-third display area DA1-3.

According to one embodiment, the display panel 104 may further include a circuit structure. For example, the circuit structure may be disposed on one side (e.g., a left side or a right side) or both sides (e.g., the left and right sides) of the display area. The circuit structure may be disposed in the first-third display area DA1-3. The circuit structure may include a gate driver, an emission signal driver, and the like. The circuit structure may include a plurality of circuit transistors T3a and T3b.

A light emitting diode LEDe may be disposed in the non-overlapping area NOA of the second display area DA2 that is adjacent to the first-third display area DA1-3. The first transistor T1e connected to the light emitting diode LEDe may be disposed in the non-overlapping area NOA of the second display area DA2. For example, the first transistor T1e may overlap the light emitting diode LEDe. In other words, both the light emitting diode LEDe and the first transistor T1e may be disposed in the non-overlapping area NOA of the second display area DA2 that has stretchable and/or contractible characteristics in the first direction D1 and does not overlap the folding area FA.

Referring to FIG. 13b, light emitting diodes LEDa′ and LEDb′ and the first transistors T1a′ and T1b′ may be disposed in the first-first display area DA1-1 that is disposed close to the overlapping area OA of the second display area DA2. A light emitting diode LEDc′ and the first transistors T1c′ and T1d′ may be disposed in the first-second display area DA1-2 that is disposed close to the overlapping area OA of the second display area DA2. A light emitting diode LEDd′ and circuit transistors T3a′ and T3b′ may be disposed in the first-third display area DA1-3 that is disposed adjacent to the overlapping area OA of the second display area DA2.

A light emitting diode LEDe′ may be disposed in the overlapping area OA of the second display area DA2 that is disposed adjacent to the first-third display area DA1-3. A first transistor connected to the light emitting diode LEDe′ may not be disposed in the overlapping area OA of the second display area DA2. In other words, the light emitting diode LEDe′ may be disposed in the overlapping area OA of the second display area DA2 that has stretchable and/or contractible characteristics in the first direction D1 and overlaps the folding area FA, whereas the first transistor connected to the light emitting diode LEDe′ may not be disposed in the overlapping area OA of the second display area DA2 that has stretchable and/or contractible characteristics in the first direction D1 and overlaps the folding area FA.

According to one embodiment, the first transistor connected to the light emitting diode LEDe′ may be disposed in the first-second display area DA1-2. The light emitting diode LEDe′ may be connected to the first transistor through a connection electrode CE4′.

According to one embodiment, the first transistor connected to the light emitting diode LEDe′ may be the first transistor T1d′ connected to the light emitting diode LEDd′ or the first transistor T1c′ connected to the light emitting diode LEDc′. According to one embodiment, the first transistor connected to the light emitting diode LEDe′ may be a first transistor that is not connected to another light emitting diode.

According to one embodiment, a first resolution of the first-first display area DA1-1 may be greater than each of a second resolution of the first-second display area DA1-2 and a third resolution of the first-third display area DA1-3. In other words, a number of light emitting diodes per unit area of the first-first display area DA1-1 may be greater than each of a number of light emitting diodes per unit area of the first-second display area DA1-2 and a number of light emitting diodes per unit area of the first-third display area DA1-3.

According to one embodiment, a fourth resolution of the second display area DA2 may be smaller than the first resolution. In other words, a number of light emitting diodes per unit area of the second display area DA2 may be smaller than the number of light emitting diodes per unit area of the first-first display area DA1-1.

According to one embodiment, the second resolution, the third resolution, and the fourth resolution may be substantially equal to each other. In other words, the number of light emitting diodes per unit area of the first-second display area DA1-2, the number of light emitting diodes per unit area of the first-third display area DA1-3, and the number of light emitting diodes per unit area of the second display area DA2 may be substantially equal to each other.

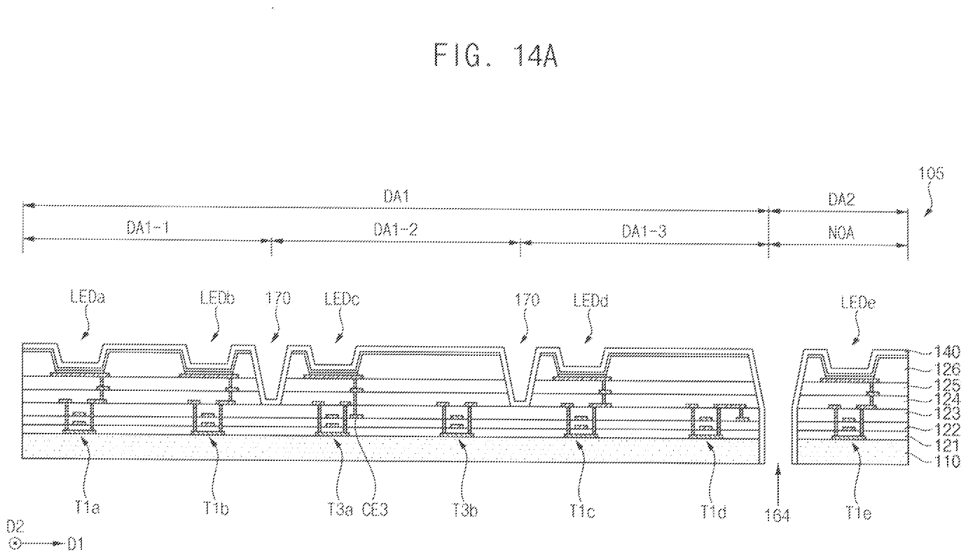

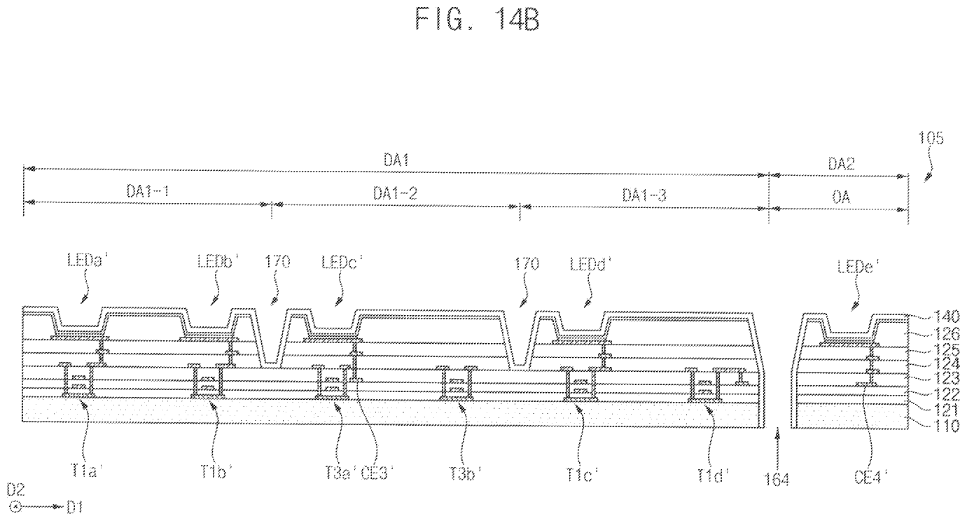

FIGS. 14a and 14b are sectional views showing a display panel according to one embodiment of the present disclosure. A display panel 105 according to one embodiment, which will be described with reference to FIGS. 14a and 14b, may be substantially identical or similar to the display panel 104 according to one embodiment, which has been described with reference to FIGS. 13a and 13b, except that the circuit transistors T3a, T3a′, T3b, and T3b′ are disposed in the first-second display area DA1-2, and the first transistors T1c, T1c′, T1d, and T1d′ are disposed in the first-third display area DA1-3. Therefore, redundant descriptions thereof will be omitted or briefly given.

Referring to FIG. 14a, light emitting diodes LEDa and LEDb and the first transistors T1a and T1b may be disposed in the first-first display area DA1-1 that is disposed close to the non-overlapping area NOA of the second display area DA2.

A light emitting diode LEDc and the circuit transistors T3a and T3b may be disposed in the first-second display area DA1-2 that is disposed close to the non-overlapping area NOA of the second display area DA2. A first transistor connected to the light emitting diode LEDc may not be disposed in the first-second display area DA1-2. In other words, the light emitting diode LEDc may be disposed in the first-second display area DA1-2, whereas the first transistor connected to the light emitting diode LEDc may not be disposed in the first-second display area DA1-2.

A light emitting diode LEDd may be disposed in the first-third display area DA1-3 that is disposed adjacent to the non-overlapping area NOA of the second display area DA2. The first transistor T1c connected to the light emitting diode LEDd may be disposed in the first-third display area DA1-3. For example, the first transistor T1c may overlap the light emitting diode LEDd.

According to one embodiment, the first transistor connected to the light emitting diode LEDc disposed in the first-second display area DA1-2 may be disposed in the first-third display area DA1-3. The light emitting diode LEDc may be connected to the first transistor in the first-third display area DA1-3 through the connection electrode CE3.

According to one embodiment, the first transistor connected to the light emitting diode LEDc may be the first transistor T1d that is not connected to another light emitting diode.

According to one embodiment, the first transistor connected to the light emitting diode LEDc may be the first transistor T1c connected to the light emitting diode LEDd.

A light emitting diode LEDe and the first transistor T1e may be disposed in the non-overlapping area NOA of the second display area DA2 that is disposed adjacent to the first-third display area DA1-3.

Referring to FIG. 14b, light emitting diodes LEDa′ and LEDb′ and the first transistors T1a′ and T1b′ may be disposed in the first-first display area DA1-1 that is disposed close to the overlapping area OA of the second display area DA2. A light emitting diode LEDc′ and the circuit transistors T3a′ and T3b′ may be disposed in the first-second display area DA1-2 that is disposed close to the overlapping area OA of the second display area DA2. A light emitting diode LEDd′ and the first transistors T1c′ and T1d′ may be disposed in the first-third display area DA1-3 that is disposed adjacent to the overlapping area OA of the second display area DA2.

A light emitting diode LEDe′ may be disposed in the overlapping area OA of the second display area DA2 that is adjacent to the first-third display area DA1-3. A first transistor connected to the light emitting diode LEDe′ may not be disposed in the overlapping area OA of the second display area DA2.

According to one embodiment, the first transistor connected to the light emitting diode LEDe′ may be disposed in the first-third display area DA1-3. The light emitting diode LEDe′ may be connected to the first transistor in the first-third display area DA1-3 through the connection electrode CE4′.

For example, the first transistor connected to the light emitting diode LEDe′ may be the first transistor T1c′ connected to the light emitting diode LEDd′ or the first transistor T1d′ connected to the light emitting diode LEDc′.

As another example, the first transistor connected to the light emitting diode LEDe′ may be a first transistor that is not connected to another light emitting diode.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display panel comprising:
a substrate including a first display area and a second display area which is disposed adjacent to the first display area and stretchable; and
light emitting diodes disposed in the first display area and the second display area on the substrate,
wherein the second display area includes first through-parts extending in a first direction and second through-parts extending in a second direction that is perpendicular to the first direction.

2. The display panel of claim 1, wherein the first through-parts and the second through-parts are alternately arranged in the first direction and the second direction.

3. The display panel of claim 1, wherein the second display area is disposed adjacent to the first display area in the second direction and stretchable in the second direction.

4. The display panel of claim 3, wherein a first width of each of the first through-parts in the second direction is greater than a second width of each of the second through-parts in the first direction.

5. The display panel of claim 3, wherein the substrate includes a folding area folded about a folding axis and extending in the first direction, and
wherein the folding area overlaps the first display area and spaced apart from the second display area.

6. The display panel of claim 1, wherein the second display area is disposed adjacent to the first display area in the first direction and stretchable in the first direction.

7. The display panel of claim 6, wherein a first width of each of the first through-parts in the second direction is smaller than a second width of each of the second through-parts in the first direction.

8. The display panel of claim 6, wherein the substrate includes a folding area folded about a folding axis and extending in the first direction, and
wherein the folding area overlaps each of the first display area and the second display area.

9. The display panel of claim 8, further comprising pixel circuits disposed on the substrate and connected to the light emitting diodes, respectively,
wherein the second display area includes:
an overlapping area overlapping the folding area and a non-overlapping area spaced apart from the folding area,
a first pixel circuit connected to a first light emitting diode disposed in the non-overlapping area and disposed in the non-overlapping area, and
a second pixel circuit connected to a second light emitting diode disposed in the overlapping area and disposed in the first display area that is disposed adjacent to the overlapping area.

10. The display panel of claim 9, wherein the first display area includes a first-first display area, a first-second display area disposed between the first-first display area and the second display area, and a first-third display area disposed between the first-second display area and the second display area, and
wherein a first resolution of the first-first display area is greater than each of a second resolution of the first-second display area and a third resolution of the first-third display area.

11. The display panel of claim 10, wherein a third pixel circuit connected to a third light emitting diode disposed in the first-first display area is disposed in the first-first display area, and
wherein a fourth pixel circuit connected to a fourth light emitting diode disposed in the first-second display area and a fifth pixel circuit connected to a fifth light emitting diode disposed in the first-third display area are disposed in the first-second display area.

12. The display panel of claim 11, wherein the second pixel circuit is disposed in the first-second display area.

13. The display panel of claim 11, further comprising a circuit structure disposed in the first-third display area on the substrate.

14. The display panel of claim 10, wherein a third pixel circuit connected to a third light emitting diode disposed in the first-first display area is disposed in the first-first display area, and
a fourth pixel circuit connected to a fourth light emitting diode disposed in the first-second display area and a fifth pixel circuit connected to a fifth light emitting diode disposed in the first-third display area are disposed in the first-third display area.

15. The display panel of claim 14, wherein the second pixel circuit is disposed in the first-third display area.

16. The display panel of claim 14, further comprising a circuit structure disposed in the first-second display area on the substrate.

17. The display panel of claim 1, wherein the second display area includes:
a second-first display area disposed adjacent to the first display area in the second direction and stretchable in the second direction;
a second-second display area disposed adjacent to the first display area in the first direction and stretchable in the first direction; and
a second-third display area disposed between the second-first display area and the second-second display area, and stretchable in a third direction between the first direction and the second direction.

18. The display panel of claim 17, wherein a first width of each of the first through-parts formed in the second-third display area in the second direction is equal to a second width of each of the second through-parts formed in the second-third display area in the first direction.

19. The display panel of claim 1, wherein the first through-parts and the second through-parts are formed through the substrate.

20. A display device comprising:
a display panel including a first display area and a second display area disposed adjacent to the first display area in a first direction and stretchable in the first direction;
a supporter disposed under the display panel and including a hinge overlapping a folding axis, a first support part spaced apart from the second display area, and a second support part overlapping the second display area; and
a housing accommodating the display panel and the supporter, and including a first housing overlapping the first support part, and a second housing overlapping the second support part,
wherein the second display area includes first through-parts extending in the first direction and second through-parts extending in a second direction that is perpendicular to the first direction.

21. The display device of claim 20, wherein the second support part or the second housing is configured to guide stretching and contraction of the second display area of the display panel in the first direction.

22. The display device of claim 20, wherein the first through-parts and the second through-parts are formed through the substrate.
